(19) United States
(12) Patent Application Publication
(10) Pub. No.: US 2014/0175286 A1
(43) Pub. Date: Jun. 26, 2014

(54) High Operating Temperature Quantum Dot Infrared Detector

(71) Applicant: Jarrod Vaillancourt, Rindge, NH (US)

(72) Inventor: Jarrod Vaillancourt, Rindge, NH (US)

(21) Appl. No.: 14/138,395

(22) Filed: Dec. 23, 2013

Related U.S. Application Data
(60) Provisional application No. 61/745,249, filed on Dec. 21, 2012.

(51) Int. Cl. H01L 31/0352

(52) U.S. Cl. CPC H01L 31/035236
USPC 250/338.4; 257/21

(57) ABSTRACT

Methods and systems for electromagnetic detection are disclosed, including providing a high operating temperature quantum dot infrared photodetector comprising: a substrate; a bottom contacting layer atop the substrate; one or more active regions atop the bottom contacting layer; and a top contacting layer atop the one or more active regions; and exposing the high operating temperature quantum dot infrared photodetector to electromagnetic waves. Other embodiments are described and claimed.

### CROSS REFERENCE TO RELATED APPLICATIONS

This application claims the benefit of the filing date of U.S. Provisional Patent Application Ser. No. 61/745,249, filed on Dec. 21, 2012, entitled “High Operating Temperature Quantum Dot Infrared Detector,” the entire disclosure of which is hereby incorporated by reference into the present disclosure.

### STATEMENT REGARDING FEDERALLY SPONSORED RESEARCH

This invention was made with government support under contract FA9453-07-C-0075 awarded by the United States Air Force. The government has certain rights in the invention.

### BACKGROUND

The invention relates generally to the field of high operating temperature infrared detectors. More particularly, the invention relates to an innovative quantum dot infrared photodetector which utilizes a barrier layer within the active region layers to reduce the dark current.

### SUMMARY

In one respect, disclosed is a high operating temperature infrared detector comprising: a substrate; a bottom contacting layer atop the substrate; one or more active regions atop the bottom contacting layer; a top contacting layer atop the one or more active regions; a first electrode in electrical continuity with the top contacting layer; and a second electrode in electrical continuity with the bottom contacting layer; wherein at least one of the one or more active regions comprises: an InAs floating layer; a first In_{0.15}Ga_{0.85}As well atop the InAs floating layer; an InAs wetting layer atop the first In_{0.15}Ga_{0.85}As well; an InAs QD layer atop the InAs wetting layer; a second In_{0.15}Ga_{0.85}As well atop the InAs QD layer; a first GaAs spacer atop the second In_{0.15}Ga_{0.85}As well; an Al_{0.10}Ga_{0.90}As barrier atop the first GaAs spacer; and a second GaAs spacer atop the Al_{0.10}Ga_{0.90}As barrier layer; wherein the bottom contacting layer comprises: a first GaAs buffer; an n⁺ GaAs contacting layer atop the first GaAs buffer; and a second GaAs buffer atop the n⁺ GaAs contacting layer; wherein the top contacting layer comprises: a GaAs buffer; and an n⁺ GaAs contacting layer atop the GaAs buffer; and wherein the substrate comprises GaAs.

In another respect, disclosed is a high operating temperature focal plane array infrared detector comprising: an array of infrared photodetectors; and electrical interconnections to the array of micro photodetectors; wherein at least one infrared photodetector of the array of infrared photodetectors comprises: a substrate; a bottom contacting layer atop the substrate; one or more active regions atop the bottom contacting layer; a top contacting layer atop the one or more active regions; a first electrode in electrical continuity with the top contacting layer; and a second electrode in electrical continuity with the bottom contacting layer; wherein at least one of the one or more active regions comprises: an InAs floating layer; a first In_{0.15}Ga_{0.85}As well atop the InAs floating layer; an InAs wetting layer atop the first In_{0.15}Ga_{0.85}As well; an InAs QD layer atop the InAs wetting layer; a second In_{0.15}Ga_{0.85}As well atop the InAs QD layer; a first GaAs spacer atop the second In_{0.15}Ga_{0.85}As well; an Al_{0.10}Ga_{0.90}As barrier atop the first GaAs spacer; and a second GaAs spacer atop the Al_{0.10}Ga_{0.90}As barrier layer; wherein the bottom contacting layer comprises: a first GaAs buffer; an n⁺ GaAs contacting layer atop the first GaAs buffer; and a second GaAs buffer atop the n⁺ GaAs contacting layer; wherein the top contacting layer comprises: a GaAs buffer; and an n GaAs contacting layer atop the GaAs buffer; and wherein the substrate comprises GaAs.

In another respect, disclosed is a method of electromagnetic detection comprising: providing a high operating temperature quantum dot infrared photodetector comprising: a substrate; a bottom contacting layer atop the substrate; one or more active regions atop the bottom contacting layer; a top contacting layer atop the one or more active regions; a first electrode in electrical continuity with the top contacting layer; and a second electrode in electrical continuity with the bottom contacting layer; and exposing the high operating temperature quantum dot infrared photodetector to electromagnetic waves.

Numerous additional embodiments are also possible.

### BRIEF DESCRIPTION OF THE DRAWINGS Other objects and advantages of the invention may become apparent upon reading the detailed description and upon reference to the accompanying drawings.

FIG. 1 is a cross-sectional schematic diagram illustrating a high operating temperature quantum dot infrared photodetector, in accordance with some embodiments.

FIG. 2 is a simplified energy band diagram of one layer of the active region of a high operating temperature quantum dot infrared photodetector, in accordance with some embodiments.

FIG. 3 shows the detailed growth parameters for a high operating temperature quantum dot infrared photodetector, in accordance with some embodiments.

FIG. 4 illustrates the dark current reduction of the high operating temperature quantum dot infrared photodetector, in accordance with some embodiments.

FIG. 5 illustrates the basic fabrication steps of a focal plane array of the high operating temperature quantum dot infrared photodetector, in accordance with some embodiments.

FIG. 6 is a schematic illustration of the focal plane array of the high operating temperature quantum dot infrared photodetector, in accordance with some embodiments.

FIG. 7 is a schematic illustration of the flip chip hybridization process of the focal plane array of the high operating temperature quantum dot infrared photodetector with a readout integrated circuit, in accordance with some embodiments.

FIG. 8 is a photograph of the focal plane array of the high operating temperature quantum dot infrared photodetector mounted in a leadless ceramic chip carrier, in accordance with some embodiments.

FIG. 9 is an image from the focal plane array of the high operating temperature quantum dot infrared photodetector, in accordance with some embodiments.

FIG. 10 is a block diagram illustrating a method for high operating temperature quantum dot infrared photodetection, in accordance with some embodiments.

While the invention is subject to various modifications and alternative forms, specific embodiments thereof are shown by way of example in the drawings and the accompanying detailed description. It should be understood, however, that the drawings and detailed description are not intended to limit the invention to the particular embodiments. This disclosure is instead intended to cover all modifications, equivalents, and alternatives falling within the scope of the present invention as defined by the appended claims.

### DETAILED DESCRIPTION

One or more embodiments of the invention are described below. It should be noted that these and any other embodiments are exemplary and are intended to be illustrative of the invention rather than limiting. While the invention is widely applicable to different types of systems, it is impossible to include all of the possible embodiments and contexts of the invention in this disclosure. Upon reading this disclosure, many alternative embodiments of the present invention will be apparent to persons of ordinary skill in the art.

Achieving high operating temperatures, such as room temperature at 298 K, for infrared photodetector cameras and detection systems has the benefit of a reduction of overall size, weight, and power consumption since cryogenic cooling is no longer required. By eliminating the cooling requirements, the overall reliability of the system is also enhanced.

In order to achieve high operating temperature infrared detection, it is necessary to reduce the dark current of the detector. One way of achieving dark current reduction in a quantum dot infrared photodetector is by the use of a barrier layer within the active region of the quantum dot. The barrier layer is integral to each layer of the active region. With such a design, it is possible to achieve high operating temperature infrared detection.

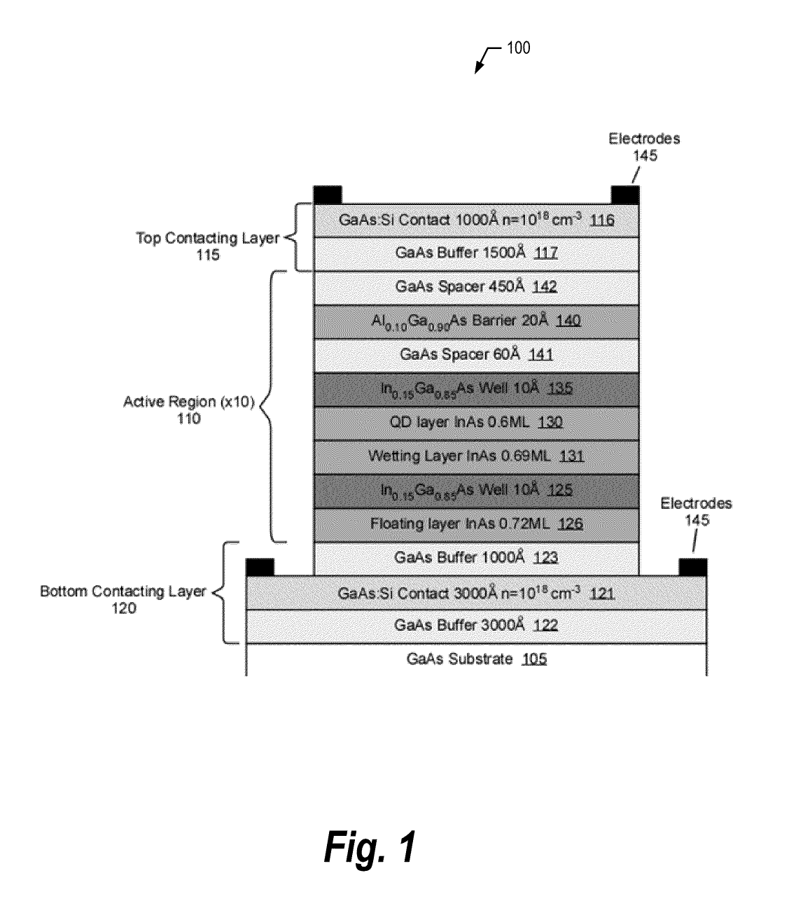

FIG. 1 is a cross-sectional schematic diagram illustrating a high operating temperature quantum dot infrared photodetector, in accordance with some embodiments.

In some embodiments, the quantum dot infrared photodetector (QDIP) 100 comprises ten layers of vertically stacked Active Regions 110, including barrier layers within each active region layer, sandwiched between a Top Contacting Layer 115 and a Bottom Contacting Layer 120, which is all grown atop a GaAs substrate 105. Each Active Region 110 layer comprises a 1 nm In_{0.15}Ga_{0.85}As bottom well layer 125 atop a 0.72 monolayer (ML) InAs floating layer 126, a 0.6 ML InAs quantum dot (QD) layer 130 atop a 0.69 ML InAs wetting layer 131, a 1 nm In_{0.15}Ga_{0.85}As top well layer 135, and a 2 nm Al_{0.10}Ga_{0.90}As dark current blocking barrier layer 140 sandwiched between a 60 Å bottom GaAs spacer layer 141 and a 450 Å top GaAs spacer layer 142. The Top Contacting Layer 115 comprises a silicon doped (n⁺) 100 nm GaAs contact layer (n=10¹⁸ cm⁻³) 116 atop a 150 nm GaAs buffer layer 117. The Bottom Contacting Layer 120 comprises a silicon doped (n⁺) 300 nm GaAs contact layer (n=10¹⁸ cm⁻³) 121 sandwiched between a 300 nm bottom GaAs buffer layer 122 and a 100 nm top GaAs buffer layer 123. Electrodes 145 are used to make electrical connections to the QDIP. Other concentration ratios for AlGaAs and InGaAs are possible, for the barrier layer and well layers, respectively.

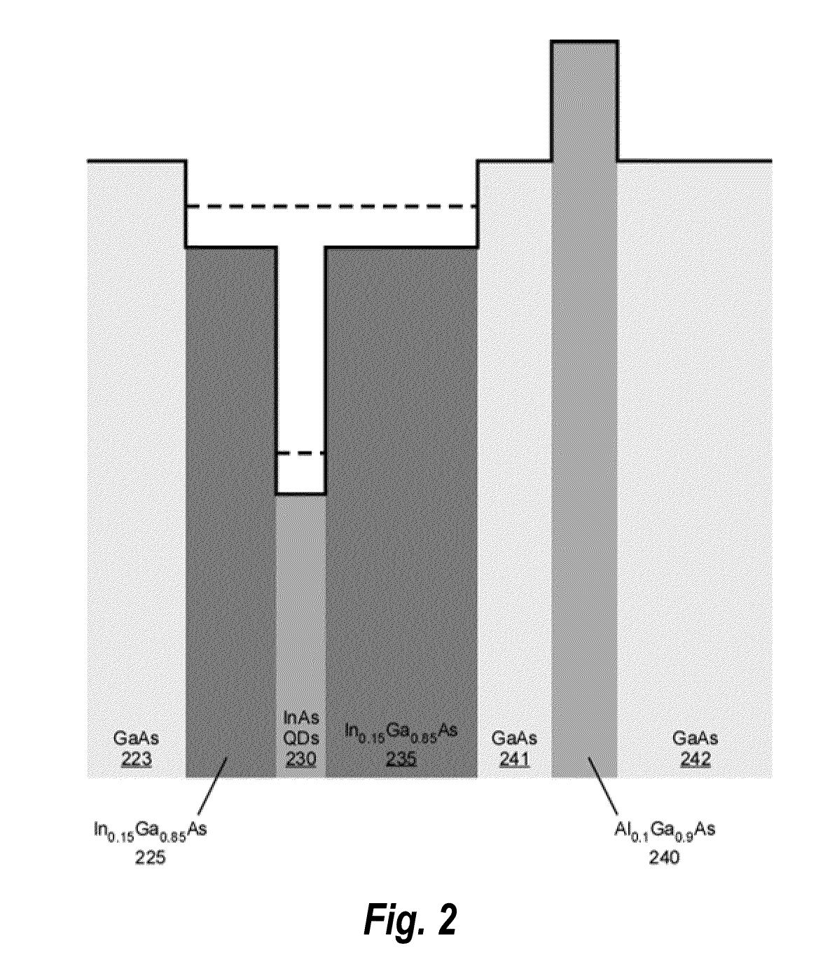

FIG. 2 is a simplified energy band diagram of one layer of the active region of a high operating temperature quantum dot infrared photodetector, in accordance with some embodiments.

FIG. 2 illustrates a simplified energy band diagram of one layer of the active region of the QDIP of FIG. 1. The left side of the band diagram illustrates the GaAs layer 223 of the Bottom Contacting Layer, followed by the InAs QD 230 sandwiched between the bottom In_{0.15}Ga_{0.85}As well 225 and the top In_{0.15}Ga_{0.85}As well 235. Next, the Al_{0.10}Ga_{0.90}As dark current blocking barrier layer 240 is sandwiched between the bottom GaAs spacer layer 241 and the top GaAs spacer layer 242. The Al_{0.10}Ga_{0.90}As dark current blocking barrier layer 240 has the highest energy band level of the QDIP.

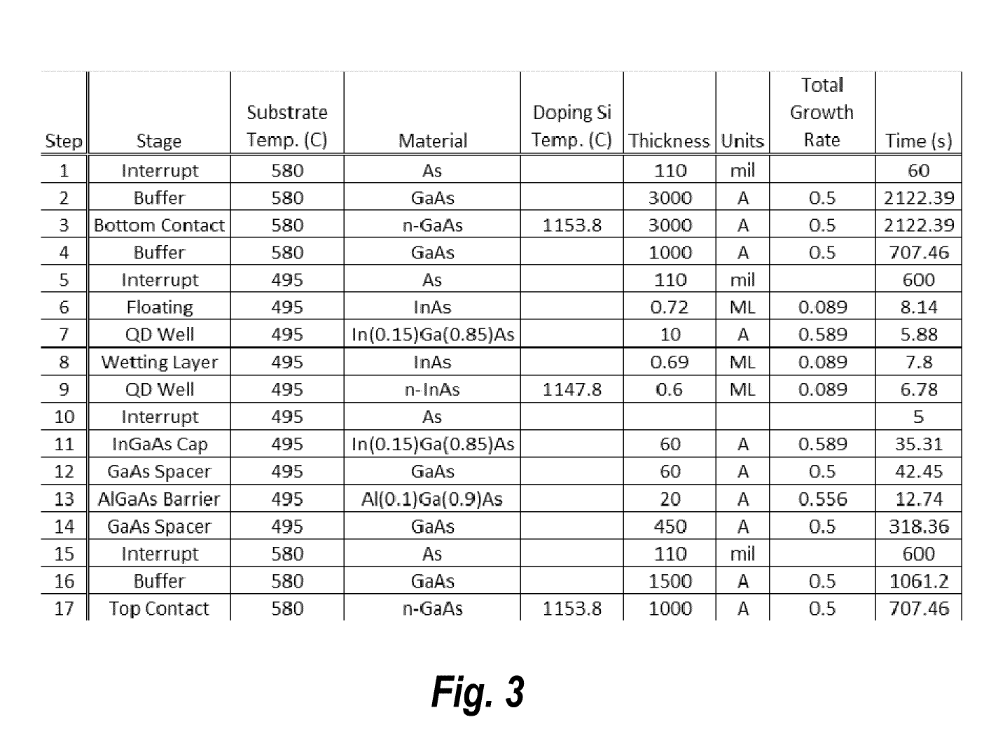

FIG. 3 shows the detailed growth parameters for a high operating temperature quantum dot infrared photodetector, in accordance with some embodiments.

In some embodiments, the high operating temperature quantum dot infrared photodetector is grown atop a GaAs substrate in a V80H molecular beam epitaxy system. Processing begins at Step 1, an interrupt stage, where the GaAs substrate is brought to 580° C. under an Arsenic (As) environment. Next, processing steps 2-4 grow the bottom contacting layer. At Step 2, a 3000 Å GaAs bottom buffer layer is grown for 2,122.39 seconds at a total growth rate of 0.5 monolayers per second (ML/sec). At Step 3, a 3000 Å silicon doped GaAs contact layer is grown with doping silicon at 1,153.8° C. for 2,122.39 seconds at a total growth rate of 0.5 ML/sec. At Step 4, a 1000 Å GaAs top buffer layer is grown for 707.46 seconds at a total growth rate of 0.5 ML/sec. After the bottom contacting layer is grown, the substrate is allowed to cool to 495° C. under As for 600 seconds at interrupt Step 5. After the substrate has cooled, processing steps 6-14 grow the active region layers. Steps 6-14 are repeated ten times in this embodiment. At Step 6, a 0.72 ML InAs floating layer is grown for 8.14 seconds at a total growth rate of 0.089 ML/sec. At Step 7, a 10 Å In_{0.15}Ga_{0.85}As well layer is grown for 5.88 seconds at a total growth rate of 0.589 ML/sec. At Step 8, a 0.69 ML InAs wetting layer is grown for 7.8 seconds at a total growth rate of 0.089 ML/sec. At Step 9, a 0.6 ML silicon doped InAs QD layer is grown with doping silicon at 1,147.8° C. for 6.78 seconds at a total growth rate of 0.089 ML/sec. Afterwards, growth is paused for 5 seconds under an Arsenic flux at interrupt Step 10. At Step 11, a 60 Å In_{0.15}Ga_{0.85}As cap layer is grown for 35.31 seconds at a total growth rate of 0.589 ML/sec. At Step 12, a 60 Å GaAs bottom spacer layer is grown for 42.45 seconds at a total growth rate of 0.5 ML/sec. At Step 13, a 20 Å Al_{0.10}Ga_{0.90}As dark current blocking barrier layer is grown for 12.74 seconds at a total growth rate of 0.556 ML/sec. At Step 14, a 450 Å GaAs top spacer layer is grown for 318.36 seconds at a total growth rate of 0.5 ML/sec. After the active region layers are grown, the substrate is heated up to 580° C. under As for 600 seconds at interrupt Step 15. Next, processing steps 16 and 17 grow the top contacting layer. At Step 16, a 1500 Å GaAs buffer layer is grown for 1061.2 seconds at a total growth rate of 0.5 ML/sec. Finally, at Step 17, a 1000 Å silicon doped GaAs contact layer is grown with doping silicon at 1,153.8° C. for 707.46 seconds at a total growth rate of 0.5 ML/sec. After completion of steps 1-17, the substrate is cooled under an Arsenic flux.

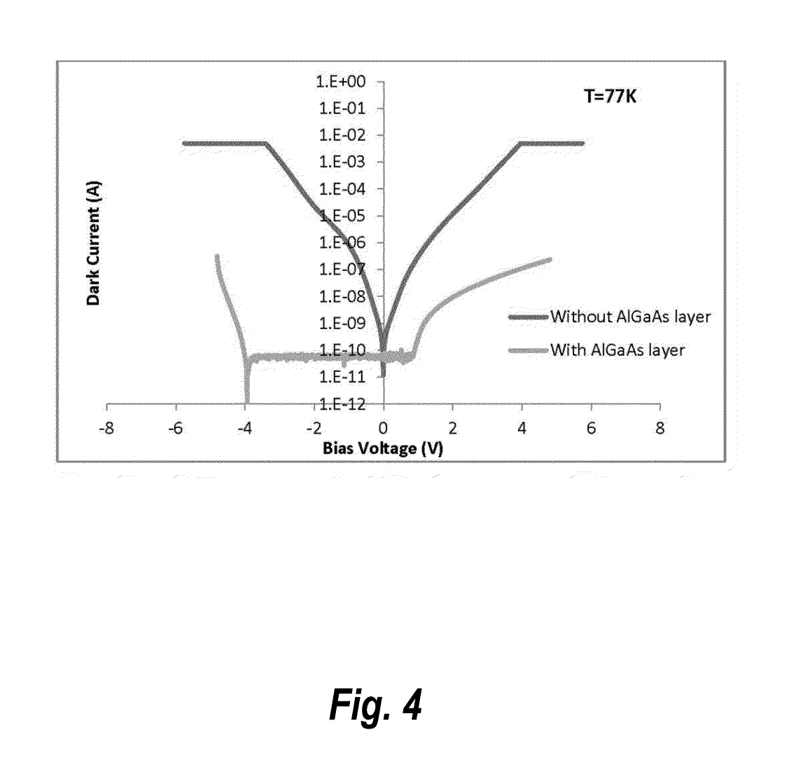

FIG. 4 illustrates the dark current reduction of the high operating temperature quantum dot infrared photodetector, in accordance with some embodiments.

The Al_{0.10}Ga_{0.90}As barrier layer grown in Step 13 of the detailed growth parameters of FIG. 3 reduces the dark current across a broad range of bias voltages. FIG. 4 shows the dark current in amps versus bias voltage for a QDIP at 77 K with an Al_{0.10}Ga_{0.90}As barrier layer and without an Al_{0.10}Ga_{0.90}As barrier layer. With the Al_{0.10}Ga_{0.90}As barrier layer, the dark current is reduced by up to nearly eight orders of magnitude compared to the QDIP without the Al_{0.10}Ga_{0.90}As barrier layer. Additionally, the QDIP with the Al_{0.10}Ga_{0.90}As barrier layer exhibits a relatively flat dark current across a broad range of bias voltages.

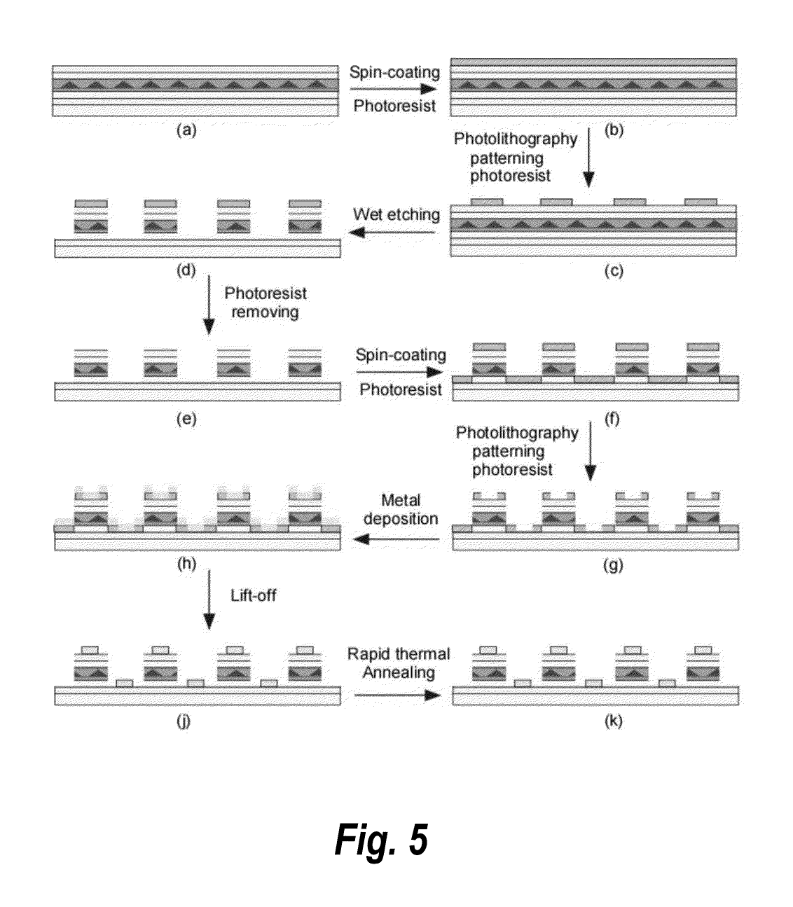

FIG. 5 illustrates the basic fabrication steps of a focal plane array of the high operating temperature quantum dot infrared photodetector, in accordance with some embodiments.

After the processing of the detailed growth parameters for a high operating temperature quantum dot infrared photodetector of FIG. 3, the grown sample (a) is processed into a focal plane array. First, from (a) to (b), photoresist is spun coat onto the grown sample. From (b) to (c), the photoresist is photolithographically patterned into an array of 640 by 512 which results in the pixels of the QDIP. From (c) to (d), the sample is wet etched down to the substrate. Afterwards, the photoresist is removed in going from (d) to (e). Next, the electrodes to the pixels of the QDIP are fabricated. From (e) to (f), photoresist is spun coat onto the wet etched sample. From (f) to (g), the photoresist is photolithographically patterned into electrodes for the pixels of the QDIP. From (g) to (h), an N-type (Ni(50 Å)/Ge(170 Å)/Au(330 Å)/Ni(150 Å)/Au(3000 Å)) alloy is deposited onto the sample by the standard E-beam metal evaporation deposition. Afterwards, from (h) to (j), a lift-off procedure is done to remove the excess deposited metal alloy. Then, from (j) to (k), the sample undergoes a rapid thermal annealing. Finally, Indium bumps are placed atop each metal contact electrode in a similar metal evaporation deposition and lift-off process as the electrodes.

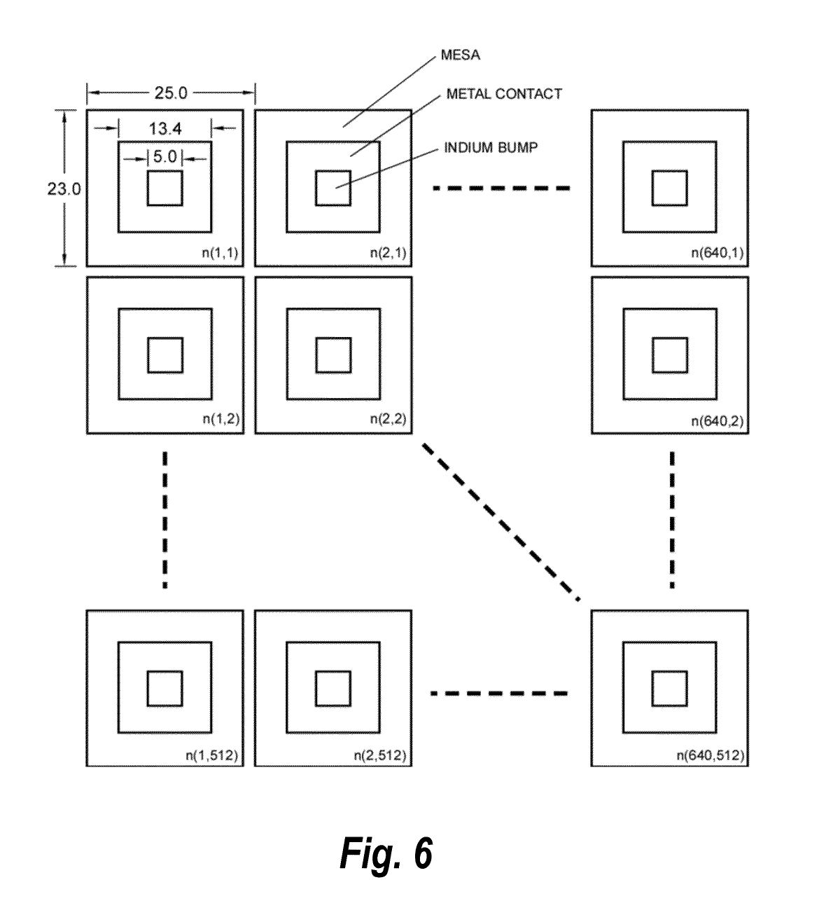

FIG. 6 is a schematic illustration of the focal plane array of the high operating temperature quantum dot infrared photodetector, in accordance with some embodiments.

After the processing steps of FIG. 5, a 640 by 512 focal plane array results. Each of the 327,680 pixels comprises a 23 μm by 23 μm mesa. The mesas have a center to center spacing of 25 μm, a 13.4 μm by 13.4 μm metal contact, and a 5.0 μm by 5.0 μm Indium bump. The center to center spacing of 25 μm is illustrated in FIG. 6 from the equivalent edges of adjacent pixels n(1,1) and n(2,1).

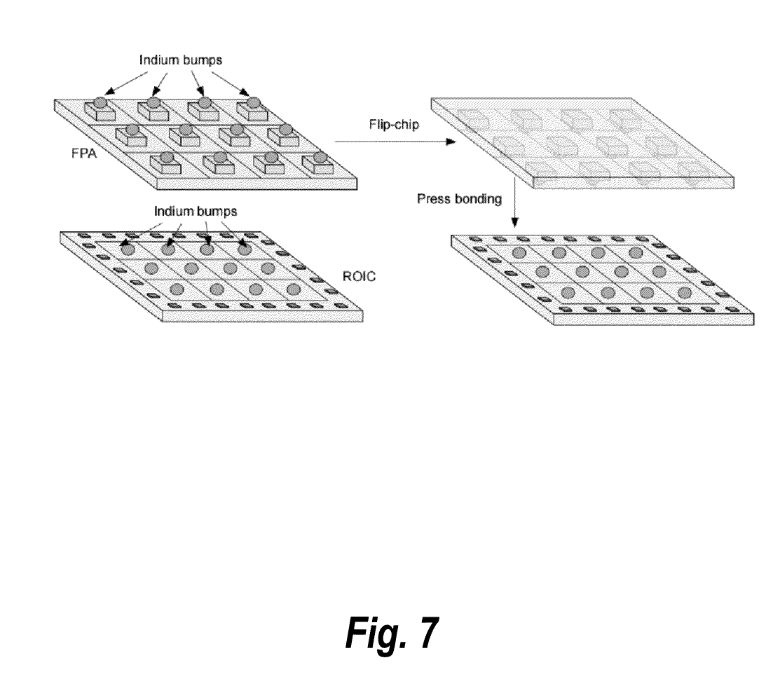

FIG. 7 is a schematic illustration of the flip chip hybridization process of the focal plane array of the high operating temperature quantum dot infrared photodetector with a readout integrated circuit, in accordance with some embodiments.

Using a flip chip hybridization process, the fabricated focal plane array (FPA) from FIG. 5 is press bound with a readout integrated circuit (ROIC). After hybridization, an epoxy is used to fill in the spaces between the focal plane array and the ROIC. In order to reduce the stress due to the mismatched coefficients of thermal expansion between the ROIC and the FPA, the GaAs substrate 105 from FIG. 1 may be mechanically removed from the FPA.

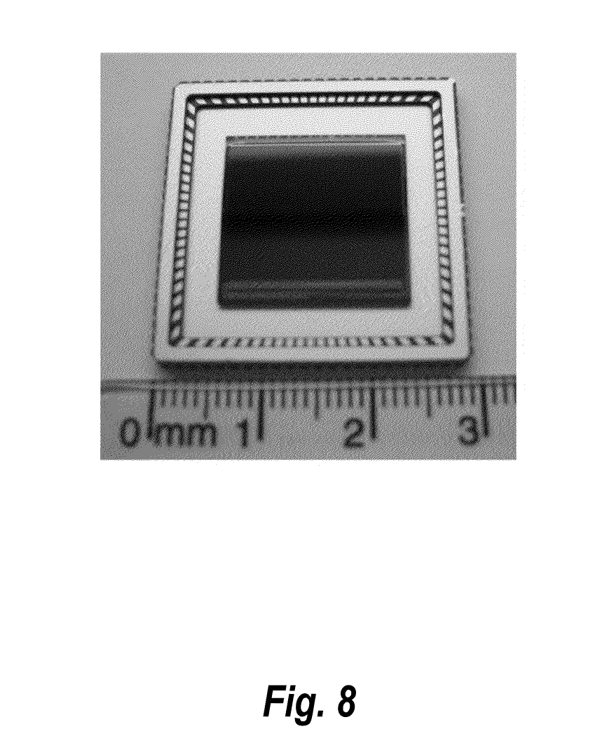

FIG. 8 is a photograph of the focal plane array of the high operating temperature quantum dot infrared photodetector mounted in a leadless ceramic chip carrier, in accordance with some embodiments.

The completed FPA device is shown in an approximately 3 cm by 3 cm leadless ceramic chip carrier. The device may then to be used to image in the infrared at high operating temperatures.

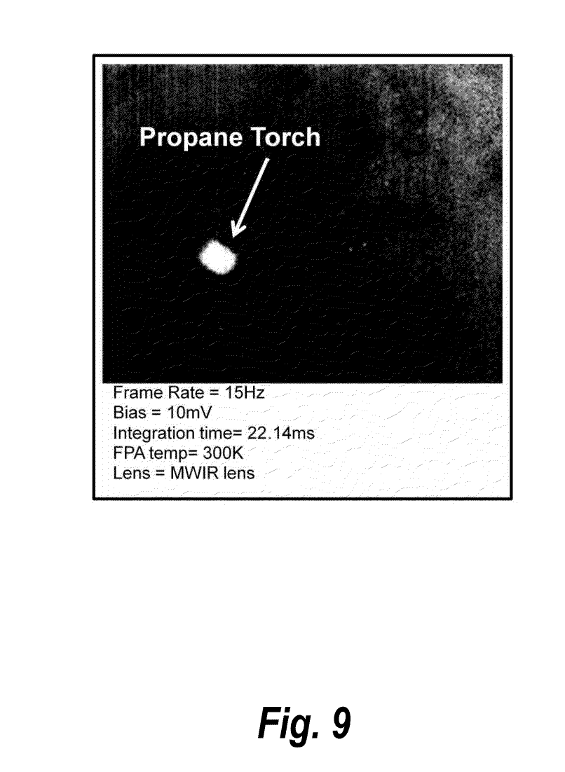

FIG. 9 is an image from the focal plane array of the high operating temperature quantum dot infrared photodetector, in accordance with some embodiments.

The device of FIG. 8 is used to image in the middle wave infrared (MWIR) at 300 K. Using a MWIR lens, a frame rate of 15 Hz, a bias of 10 mV, and an integration time of 22.14 ms, the flame from a propane torch is imaged. The image of the propane torch flame is shown in FIG. 9.

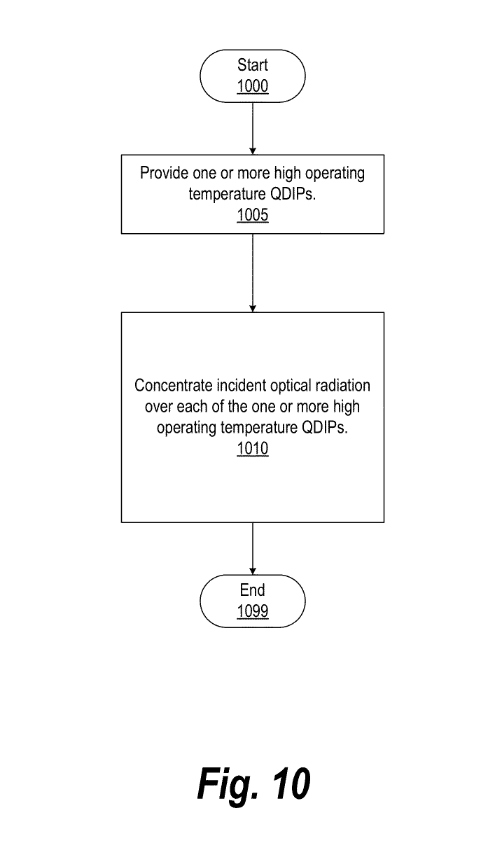

FIG. 10 is a block diagram illustrating a method for high operating temperature quantum dot infrared photodetection, in accordance with some embodiments.

In some embodiments, the method illustrated in FIG. 10 may be performed by one or more of the devices illustrated in FIGS. 1-9. Processing begins at 1000 whereupon, at block 1005, one or more high operating temperature QDIPs is provided. At block 1010, incident optical radiation is concentrated over each of the one or more high operating temperature QDIPs. Processing subsequently ends at 1099.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The benefits and advantages that may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

While the present invention has been described with reference to particular embodiments, it should be understood that the embodiments are illustrative and that the scope of the invention is not limited to these embodiments. Many variations, modifications, additions, and improvements to the embodiments described above are possible. It is contemplated that these variations, modifications, additions, and improvements fall within the scope of the invention as detailed within the following claims.

1. A high operating temperature infrared detector comprising:
a substrate;
a bottom contacting layer atop the substrate;
one or more active regions atop the bottom contacting layer; and
a top contacting layer atop the one or more active regions.

2. The high operating temperature infrared detector of claim 1, wherein at least one of the one or more active regions comprises:
a floating layer;
a first well atop the floating layer;
a wetting layer atop the first well;
a QD layer atop a wetting layer;
a second well atop the QD layer;
a first spacer atop the second well;
a barrier layer atop the first spacer; and
a second spacer atop the barrier layer.

3. The high operating temperature infrared detector of claim 2, wherein:
the floating layer comprises InAs;
the first well comprises InGaAs;
the wetting layer comprises InAs;
the QD layer comprises InAs;
the second well comprises InGaAs;
the first spacer comprises GaAs;
the barrier layer comprises AlGaAs; and
the second spacer comprises GaAs.

4. The high operating temperature infrared detector of claim 3, wherein the barrier layer comprises Al_{0.10}Ga_{0.90}As, the first well comprises In_{0.15}Ga_{0.85}As, and the second well comprises In_{0.15}Ga_{0.85}As.

5. The high operating temperature infrared detector of claim 1, wherein the bottom contacting layer comprises:
a first GaAs buffer;
an n⁺ GaAs contacting layer atop the first GaAs buffer; and
a second GaAs buffer atop the n⁺ GaAs contacting layer.

6. The high operating temperature infrared detector of claim 1, wherein the top contacting layer comprises:
a GaAs buffer; and
an n⁺ GaAs contacting layer atop the GaAs buffer.

7. The high operating temperature infrared detector of claim 1, wherein the substrate comprises GaAs.

8. The high operating temperature infrared detector of claim 1 further comprising:
a first electrode in electrical continuity with the top contacting layer; and
a second electrode in electrical continuity with the bottom contacting layer.

9. The high operating temperature infrared detector of claim 1, wherein the high operating temperature infrared detector detects electromagnetic waves ranging from about 8 microns to about 14 microns.

10. The high operating temperature infrared detector of claim 1, wherein the high operating temperature infrared detector detects electromagnetic waves ranging from about 3 microns to about 8 microns.

11. A high operating temperature focal plane array infrared detector comprising:
an array of infrared photodetectors, wherein at least one infrared photodetector of the array of infrared photodetectors comprises:
a substrate;
a bottom contacting layer atop the substrate;
one or more active regions atop the bottom contacting layer; and
a top contacting layer atop the one or more active regions; and
electrical interconnections to the array of infrared photo detectors.

12. The high operating temperature focal plane array infrared detector of claim 11, wherein at least one of the one or more active regions comprises:
a floating layer;
a first well atop the floating layer;
a wetting layer atop the first well;
a QD layer atop a wetting layer;
a second well atop the QD layer;
a first spacer atop the second well;
a barrier layer atop the first spacer; and
a second spacer atop the barrier layer.

13. The high operating temperature focal plane array infrared detector of claim 12, wherein:
the floating layer comprises InAs;
the first well comprises InGaAs ;
the wetting layer comprises InAs;
the QD layer comprises InAs;
the second well comprises InGaAs;
the first spacer comprises GaAs;
the barrier layer comprises AlGaAs; and
the second spacer comprises GaAs.

14. The high operating temperature infrared detector of claim 13, wherein the barrier layer comprises Al_{0.10}Ga_{0.90}As, the first well comprises In_{0.15}Ga_{0.85}As, and the second well comprises In_{0.15}Ga_{0.85}As.

15. The high operating temperature focal plane array infrared detector of claim 11, wherein the bottom contacting layer comprises:
a first GaAs buffer;
an n⁺ GaAs contacting layer atop the first GaAs buffer; and
a second GaAs buffer atop the n⁺ GaAs contacting layer.

16. The high operating temperature focal plane array infrared detector of claim 11, wherein the top contacting layer comprises:
a GaAs buffer; and
an n⁺ GaAs contacting layer atop the GaAs buffer.

17. The high operating temperature focal plane array infrared detector of claim 11, wherein the substrate comprises GaAs.

18. The high operating temperature focal plane array infrared detector of claim 11, wherein the at least one infrared photodetector of the array of infrared photodetectors further comprises:
a first electrode in electrical continuity with the top contacting layer; and
a second electrode in electrical continuity with the bottom contacting layer.

19. The high operating temperature focal plane array infrared detector of claim 11, wherein the high operating temperature focal plane array infrared detector detects electromagnetic waves ranging from about 8 microns to about 14 microns.

20. The high operating temperature focal plane array infrared detector of claim 11, wherein the high operating temperature focal plane array infrared detector detects electromagnetic waves ranging from about 3 microns to about 8 microns.

21. A method of electromagnetic detection comprising:
providing a high operating temperature quantum dot infrared photodetector comprising:
a substrate;
a bottom contacting layer atop the substrate;
one or more active regions atop the bottom contacting layer; and a top contacting layer atop the one or more active regions; and
exposing the high operating temperature quantum dot infrared photodetector to electromagnetic waves.

22. The method of claim 21, wherein at least one of the one or more active regions comprises:
a floating layer;
a first well atop the floating layer;
a wetting layer atop the first well;
a QD layer atop a wetting layer;
a second well atop the QD layer;
a first spacer atop the second well;
a barrier layer atop the first spacer; and
a second spacer atop the barrier layer.

23. The method of claim 21, wherein:
the floating layer comprises InAs;
the first well comprises InGaAs;
the wetting layer comprises InAs;
the QD layer comprises InAs;
the second well comprises InGaAs;
the first spacer comprises GaAs;
the barrier layer comprises ALGaAs; and
the second spacer comprises GaAs.

24. The high operating temperature infrared detector of claim 23, wherein the barrier layer comprises Al_{0.10}Ga_{0.90}As, the first well comprises In_{0.15}Ga_{0.85}As, and the second well comprises In_{0.15}Ga_{0.85}As.

25. The method of claim 21, wherein the bottom contacting layer comprises:
a first GaAs buffer;
an n⁺ GaAs contacting layer atop the first GaAs buffer; and
a second GaAs buffer atop the n⁺ GaAs contacting layer.

26. The method of claim 21, wherein the top contacting layer comprises:
a GaAs buffer; and
an n⁺ GaAs contacting layer atop the GaAs buffer.

27. The method of claim 21, wherein the substrate comprises GaAs.

28. The method of claim 21, wherein the high operating temperature quantum dot infrared photodetector further comprises:
a first electrode in electrical continuity with the top contacting layer; and
a second electrode in electrical continuity with the bottom contacting layer.
